(19) United States
(12) Patent Application Publication
(10) Pub. No.: US 2015/0267032 A1
(43) Pub. Date: Sep. 24, 2015

(54) NANOCOMPOSITES OF COPOLYMERS AND DIELECTRIC MATERIALS

(71) Applicant: DOW GLOBAL TECHNOLOGIES LLC, Midland, MI (US)

(72) Inventors: Phillip D. Hustad, Marlborough, MA (US); Stephanie L. Potisek, Houston, TX (US); Rebekah K. Feist, Midland, MI (US); James C. Stevens, Richmond, TX (US); Michael E. Mills, Midland, MI (US); Yuanqiao Rao, Freeport, TX (US); Eddy I. Garcia-Meitin, Freeport, TX (US)

(21) Appl. No.: 14/435,869

(22) PCT Filed: Oct. 14, 2013
(86) PCT No.: PCT/US2013/064820

§ 371 Date: Apr. 15, 2015

Related U.S. Application Data
(60) Provisional application No. 61/720,661, filed on Oct. 31, 2012.

(51) Int. Cl. C08K 3/22; G02B 1/111; G02B 1/04; G02B 1/08; H01L 31/0216; H01L 31/055

(52) U.S. Cl. CPC C08K 3/22; H01L 31/02168; H01L 31/055; G02B 1/04; G02B 1/08; G02B 1/111; C08K 2003/2241

(57) ABSTRACT

A composition comprising a phase separated block copolymer and an inorganic dielectric nanoparticle, wherein the nanoparticle is dispersed in the copolymer and is present primarily in one phase. For example, a Ti0₂ nanocomposite can be created via the in situ formation of Ti0₂ within a silane-grafted OBC. Taking advantage of the phase morphology of the OBC and the differential swelling of the hard and soft segments, due to their inherent crystallinity, enables the selective incorporation of Ti0₂ nanoparticles into the soft segments of the OBC.

### CROSS-REFERENCE TO RELATED APPLICATIONS

This application claims priority from provisional application Ser. No. 61/720,661, filed Oct. 31, 2012, which is incorporated herein by reference in its entirety.

### BACKGROUND OF THE INVENTION

The invention relates to composites of inorganic dielectric nanoparticles and phase-separated block copolymers, processes to make the composites, and devices made using the composites.

The manipulation of light has been a useful field of art since the invention of the optical lens. More recently, the scientific field of photonics has been widely developed for a variety of practical uses. The science of photonics includes the generation, emission, transmission, modulation, signal processing, switching, amplification, and detection/sensing of light. Applications of photonics and photonic structures are ubiquitous and growing in modern technology. Included are all areas from everyday life to the most advanced science, e.g., light detection, telecommunications, information processing, lighting, metrology, spectroscopy, holography, medicine (surgery, vision correction, endoscopy, health monitoring), military technology, laser material processing, visual art, biophotonics, agriculture, and robotics. Unique applications of photonics continue to emerge. Economically important applications for photonic devices include optical data recording, fiber optic telecommunications, laser printing (based on xerography), displays, and optical pumping of high-power lasers.

Photonic structures, especially thin-film photonic structures, can be usefully employed in a variety of consumer devices, including barcode scanners, printers, CD/DVD/Blu-ray devices, and remote control devices. In the field of telecommunications, such structures are useful for a variety of applications, including optical fiber communications and optical down conversion. The skilled artisan will appreciate that there are numerous other applications for photonic devices. One particularly useful method of fabricating photonic devices involves the production of regularly repeating structures comprising materials of differing refractive index. Examples of such structures include Bragg mirrors, gratings, wave guides, diffraction gratings, selective band-pass filters, anti-reflective coatings, etc. These devices are generally produced by vacuum depositing onto a substrate materials of differing indices of refraction. This method is useful for structures of simple geometries and having few layers, such as Bragg mirrors containing relatively few layers of a high index material alternating with a low index material.

There is a continuing need for low-cost, rapid and simple to manufacture photonic devices, for new photonic structures, and devices incorporating such structures.

It would be desirable to have improved materials that are useful in the manufacture of photonic structures. For example, it would be desirable to have materials useful for low loss optical coupling to photoelectronic devices.

### SUMMARY OF THE INVENTION

The invention includes a composition comprising a phase separated block copolymer and an inorganic dielectric nanoparticle, wherein the nanoparticle is dispersed in the copolymer and is present primarily in one phase and the composition has an S_{N} of at least 3. The invention also includes articles comprising the composition.

The composition can be prepared using a low-cost, simple, high yielding process. Surprisingly, the composition of the invention simultaneously exhibits uniquely selectively incorporated inorganic dielectric material with the appropriate feature size to be optically active in the desired wavelength ranges.

The composition is easily fabricated into articles, such as sheets and films, having the ability to manipulate light for a variety of processes and products. Structures prepared using these new materials could be, for example, efficient photonic devices.

### BRIEF DESCRIPTION OF THE DRAWINGS

FIG. 1 is phase diagram plot of the product of the degree of polymerization, N, and the Flory-Huggins interaction parameter, χ, vs. weight fraction of block A of a representative A-b-B diblock copolymer. FIG. 1 also includes a depiction of examples of the resulting morphologies.

FIG. 2 is a transmission electron micrograph of a sample of KRATON.

FIG. 3 is a schematic of a process for making a material of the invention.

FIG. 4 is a TEM image of the nanocomposite material of Example 2.

FIG. 5 is a STEM image of the nanocomposite of Example 2.

FIG. 6 is a combined image prepared by overlaying the boxed region of FIG. 5 onto a black and white version of a false color elemental map of the same region.

FIG. 7 is a backscatter SEM image of the composite of Example 2.

FIG. 8 is a TEM image of a film of the untreated phase separated OBC employed in Example 1.

FIG. 9 is a TEM image of a film of the untreated phase separated OBC employed in Example 1.

FIG. 10 is a cross section of the device of Example 3.

FIG. 11 is a cross section of the device of Example 4.

FIG. 12 is a cross section of the device of Example 5.

FIG. 13 is a block flow diagram of a process that can be used to prepare the composite of the invention.

### DETAILED DESCRIPTION OF THE INVENTION

As used herein, “a,” “an,” “the,” “at least one,” and “one or more” are used interchangeably. The terms “comprises,” “includes,” and variations thereof do not have a limiting meaning where these terms appear in the description and claims. Thus, for example, an aqueous composition that includes particles of “a” hydrophobic polymer can be interpreted to mean that the composition includes particles of “one or more” hydrophobic polymers.

Also herein, the recitations of numerical ranges by endpoints include all numbers subsumed in that range (e.g., 1 to 5 includes 1, 1.5, 2, 2.75, 3, 3.80, 4, 5, etc.). For the purposes of the invention, it is to be understood, consistent with what one of ordinary skill in the art would understand, that a numerical range is intended to include and support all possible subranges that are included in that range. For example, the range from 1 to 100 is intended to convey from 1.01 to 100, from 1 to 99.99, from 1.01 to 99.99, from 40 to 60, from 1 to 55, etc.

Also herein, the recitations of numerical ranges and/or numerical values, including such recitations in the claims, can be read to include the term “about.” In such instances the term “about” refers to numerical ranges and/or numerical values that are substantially the same as those recited herein.

As used herein, the use of the term “(meth)” followed by another term such as acrylate refers to both acrylates and methacrylates. For example, the term “(meth)acrylate” refers to either acrylate or methacrylate; the term “(meth)acrylic” refers to either acrylic or methacrylic; and the term “(meth)acrylic acid” refers to either acrylic acid or methacrylic acid.

Unless stated to the contrary, or implicit from the context, all parts and percentages are based on weight and all test methods are current as of the filing date of this application. For purposes of United States patent practice, the contents of any referenced patent, patent application or publication are incorporated by reference in their entirety (or its equivalent US version is so incorporated by reference) especially with respect to the disclosure of definitions (to the extent not inconsistent with any definitions specifically provided in this disclosure) and general knowledge in the art.

All references to the Periodic Table of the Elements and the various groups therein are to the version published in the CRC Handbook of Chemistry and Physics, 72nd Ed. (1991-1992) CRC Press, at page 1-10.

The term “copolymer” refers to a polymer derived from two (or more) monomeric species, as opposed to a homopolymer where only one monomer is used. Copolymerization refers to methods used to chemically synthesize a copolymer.

The term “block copolymer” refers to copolymers comprising two or more chemically distinct homopolymer or copolymer subunits linked by covalent bonds. The union of the chemically distinct block subunits may require an intermediate non-repeating subunit, known as a junction block. Block copolymers with two or three distinct blocks are called diblock copolymers and triblock copolymers, respectively. An example of a diblock copolymer comprising chemically distinct homopolymer subunits is, for example, PS-b-PMMA, which is shorthand chemical notation for polystyrene-b-poly(methyl methacrylate) and is usually made by first polymerizing styrene, and then subsequently polymerizing MMA from the reactive end of the polystyrene chains. This polymer is a “diblock copolymer” because it contains two different chemically distinct blocks. Triblocks, tetrablocks, multiblocks, etc. can also be made. Diblock copolymers can be made using a variety of techniques including living polymerization techniques, such as atom transfer free radical polymerization (ATRP), reversible addition fragmentation chain transfer (RAFT), ring-opening metathesis polymerization (ROMP), and living cationic or living anionic polymerizations. An emerging technique is chain shuttling polymerization. Another strategy to prepare block copolymers is the chemoselective stepwise coupling between polymeric precursors and heterofunctional linking agents.

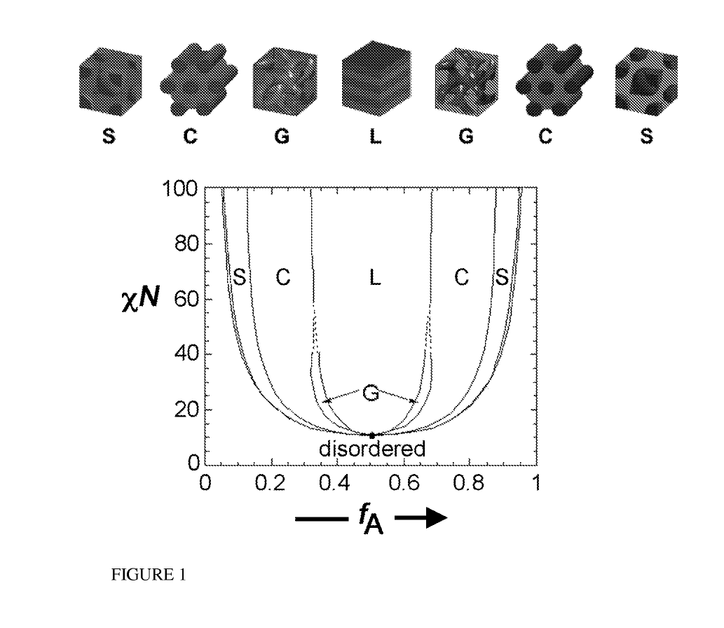

One aspect of certain block copolymers is that they can they can “microphase separate” or “mesophase separate” to form periodic nanostructures, as in the case of the commercially available styrene-butadiene-styrene triblock copolymer known as KRATON. KRATON is made by living polymerization, so that the blocks are almost monodisperse, which helps to create a very regular microstructure. Polymer scientists use thermodynamics to describe how the different blocks interact. The product of the degree of polymerization, N, and the Flory-Huggins interaction parameter, χ, gives an indication of how incompatible the two blocks are and whether or not they will microphase separate. FIG. 1 is phase diagram plot of the product of the degree of polymerization, N, and the Flory-Huggins interaction parameter, χ, vs. weight fraction of block A of a representative A-b-B diblock copolymer. FIG. 1 also includes a depiction of examples of the resulting morphologies.

Depending on the relative molecular lengths of each block, several morphologies can be obtained, as is well-known in the art. In diblock copolymers, sufficiently different block lengths lead to nanometer-sized spheres of one block in a matrix of the second (for example PMMA in polystyrene). Using less different block lengths, a “hexagonally packed cylinder” geometry can be obtained. Blocks of similar length may form layers (also called lamellae). Intermediate between the cylindrical and lamellar phase is the gyroid phase.

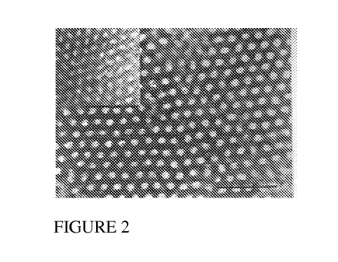

Microphase separation and mesophase separation is a phenomenon similar to that of oil and water. Oil and water are immiscible; they phase separate. Due to incompatibility between the blocks, block copolymers may undergo a similar phase separation if the chemical composition of the chemically distinct blocks are sufficiently incompatible. Because the blocks are covalently bonded to each other, they cannot demix macroscopically as in the case of water and oil. In “microphase/mesophase separation” the blocks form nanometer-sized structures. For the purposes of this patent, “microphase separation” refers to the formation of periodic nanostructures where the distance between regularly-repeating block-block interfaces of the phase separated nano structure is 40 nm or less. The term “mesophase separation” refers to the formation of periodic nanostructures where the average of the smallest distance between regularly-repeating block-block interfaces of the phase separated nanostructure is greater than 40 nm. For illustration, below is a transmission electron micrograph of a sample of KRATON, where the polybutadiene block domains have been stained using osmium tetroxide, which appears dark gray in the micrograph of FIG. 2. The polystyrene (PS) block domains have microphase separated into spheres that have on average, a spacing between the surface (the interface between the PS and PBD domains) of one sphere PS domain and the surface of neighboring spheres of approximately 32 nm. A phase separated block copolymer that forms domains consisting of lamellae that are >1000 nm in each of two dimensions, but which have a spacing between the interface of one layer and the adjacent layer of 100 nm, is be an example of a mesophase separated block copolymer, because the average smallest distance (100 nm) between the interfaces of the phase-separated layers is greater than 40 nm.

The term “refractive index”, also referred to as the “index of refraction,” is a number (n) that describes how light, or any other radiation, propagates through a medium. More fundamentally, n is defined as the factor by which the wavelength and the velocity of the radiation are reduced with respect to their vacuum values. The speed of light in a medium is v=c/n, where c is the speed in vacuum. Similarly, for a given vacuum wavelength λ₀, the wavelength in the medium is λ=λ₀/n. This implies that vacuum has a refractive index of 1. The skilled artisan will appreciate that the refractive index of a material varies with the wavelength. This is called dispersion; it causes the splitting of white light in prisms and rainbows, and chromatic aberration in lenses. In opaque media, the refractive index is a complex number: while the real part describes refraction, the imaginary part accounts for absorption. Unless otherwise specified in this application, the refractive index value refers to the value measured at the yellow doublet sodium D-line, with a wavelength of 589 nanometers.

The term “at least partially transparent” as used herein, means that at least 80% of the incident light is transmitted through the relevant structure.

The term “nanoparticle” refers to an ultrafine particle with lengths in two or three dimensions greater than about 0.001 micrometer (1 nanometer) and smaller than about 0.1 micrometer (100 nanometers), which particle may or may not exhibit a size-related intensive property.

The term “self-assembly” or “self-organization” refers to a process in which a disordered system of molecules forms an organized structure or pattern as a consequence of specific, local interactions among the molecules themselves, without external direction. An example of self-assembly is the organization of a micro- or meso-phase separated block copolymer into an ordered morphology such as a lamellar, cylindrical, spherical, or other ordered structure.

The term “selective swelling” of a phase in a phase-separated block copolymer refers to a process wherein a compound is added which is preferentially distributed (soluble) within one of the two phases so as to increase the size of the domain preferentially containing the compound. The compound used to selectively swell a phase can be a low molecular weight compound such as an oil, solvent, or other liquid, or a polymer such as high density polyethylene, polybutadiene, or any other natural or man-made polymer. Combinations of different compounds may be used to selectively swell a phase.

The terms “Polydispersity Index” or “PDI”, or “molecular weight distribution” refer to the ratio of the weight average molecular weight to the number average molecular weight (Mw/Mn) of a polymer.

The term “sol-gel process” refers to a wet-chemical technique widely used in the fields of materials science and ceramic engineering. This technique is used primarily for the fabrication of materials (typically metal oxides) starting from a colloidal solution (sol) that acts as the precursor for an integrated network (or gel) of either discrete particles or network polymers. Typical precursors are metal alkoxides and metal salts (such as chlorides, nitrates and acetates), which undergo various forms of hydrolysis and polycondensation reactions.

As used herein, the term “dielectric” refers to an insulating material whose internal electric charges do not flow freely, and which therefore does not conduct an electric current, under the influence of an electric field. Electronic band theory (a branch of physics) says that a charge will flow if states are available into which electrons can be excited. This allows electrons to gain energy and thereby move through a conductor such as a metal. If no such states are available, the material is an insulator. As used herein, dielectric materials have a large band gap. This occurs because the “valence” band containing the highest energy electrons is full, and a large energy gap separates this band from the next band above it. There is always some voltage (called the breakdown voltage) that will give the electrons enough energy to be excited into this band. Once this voltage is exceeded, the material ceases being an insulator, and charge will begin to pass through it. However, it is usually accompanied by physical or chemical changes that permanently degrade the material's insulating properties. Examples of dielectric materials include SiO₂, TiO₂, Nb₂O₅, ZrO₂. HfO₂ and the like.

The composition of the invention is prepared from a copolymer, a grafting agent, and an inorganic dielectric nanoparticle precursor. The composition can be employed in the manufacture of the articles of the invention.

The copolymer is a phase separated copolymer such as, for example, a microphase or mesophase separated copolymer.

The skilled artisan will select appropriate block copolymers for use in the practice of this invention based on a number of characteristics, which are outlined below. These general characteristics include the ability to phase separate into micro- or meso-domains, the size of the domains, domain morphology (spheres, cylinders, gyroids, or lamellae), environmental stability, cost, processability, ease of grafting of one domain over another, hardness, toughness, clarity, and the like. The domains may be regularly-repeating. Block copolymers that may be employed in this invention are those that phase separate to give a desirable phase-separated morphology with dimensions appropriate for the desired application. For example, for selectively reflecting wavelengths in the infrared portion of the spectrum, longer spacing between the mesodomains of a lamellar structure is desirable. The relationship between domain spacing and wavelength of reflected light is a function of the refractive index difference between the two phase-separated domains. For the polymers and structures of this invention intended to selectively reflect infrared radiation, it is generally desirable to employ a block copolymer that phase separates into lamellar meso-domains of >150 nm spacing, or preferably >200 nm spacing. Conversely, reflecting shorter wavelengths in the visible spectrum such as green or blue light requires smaller domain spacings.

Suitable block copolymers include diblock copolymers, triblock copolymers, and statistical multi-block copolymers such as OBC's, as described herein. Diblock and triblock copolymers with blocks covalently bonded to each other having the generalized structure AAAAA-b-BBBBB for diblocks and AAAAA-b-BBBBB-b-AAAAA for triblocks wherein AAAAA represents a block of monomer A and BBBBB represents a block of monomer B. The skilled artisan will appreciate that many such block copolymers may be used in the practice of this invention so long as the block copolymer undergoes phase separation to give the desired phase morphology. Examples of suitable diblock copolymers can be selected from those wherein one of the blocks is comprised of polystyrene, polyurethane, polyethers (such as those resulting from polymerization of ethylene oxide, propylene oxide, butylene oxide, and the like), polyolefins (including ethylene, C₃-C₁₂ alpha olefins, dienes such as 1,4-butadiene and isoprene, nornornene and substituted norbornenes and the like), polyvinyl, pyridine, polyesters, polyorganosiloxanes, polyorganogermanes, and the like.

The block copolymer undergoes self-assembly into a phase-separated morphology, and can comprise blocks comprising one or more monomers. At least two blocks in the block copolymer are compositionally, structurally, or both compositionally and structurally non-identical. The blocks themselves can be homopolymers, or copolymers, including terpolymers. The block copolymer can comprise an amphiphilic organic block copolymer, amphiphilic inorganic block copolymer, organic di-block copolymer, organic multi-block copolymer, inorganic-containing di-block copolymer, inorganic-containing multi-block copolymer, linear block copolymer, star block copolymer, dendritic block copolymer, hyperbranched block copolymer, graft block copolymer, or a combination comprising at least one of the foregoing block copolymers. In an embodiment, the block copolymer is a di-block copolymer.

In one embodiment, the blocks of the block copolymer comprise repeating units derived from C₂₋₃₀ olefinic monomers, (meth)acrylate monomers derived from C₁₋₃₀ alcohols, inorganic-containing monomers including those based on Fe, Si, Ge, Sn, Al, Ti, or a combination comprising at least one of the foregoing monomers. In a specific embodiment, exemplary monomers for use in the blocks can include, as the C₂₋₃₀ olefinic monomers, ethylene, propylene, 1-butene, 1,3-butadiene, isoprene, vinyl acetate, dihydropyran, norbornene, maleic anhydride, styrene, 4-hydroxy styrene, 4-acetoxy styrene, 4-methylstyrene, and alpha-methylstyrene; and can include as (meth)acrylate monomers, methyl(meth)acrylate, ethyl(meth)acrylate, n-propyl(meth)acrylate, isopropyl(meth)acrylate, n-butyl(meth)acrylate, isobutyl(meth)acrylate, n-pentyl(meth)acrylate, isopentyl(meth)acrylate, neopentyl(meth)acrylate, n-hexyl(meth)acrylate, cyclohexyl(meth)acrylate, isobornyl(meth)acrylate, and hydroxyethyl(meth)acrylate. Combinations of two or more of these monomers can be used. Exemplary blocks that are homopolymers include blocks prepared using styrene (i.e., polystyrene blocks), or (meth)acrylate homopolymer blocks such as poly(methyl methacrylate); exemplary random blocks include, for example, blocks of styrene and methyl methacrylate (e.g., poly(styrene-co-methyl methacrylate)), randomly copolymerized; and an exemplary alternating copolymer block can include blocks of styrene and maleic anhydride which are known to form a styrene-maleic anhydride dyad repeating structure due to the inability of maleic anhydride to homopolymerize under most conditions (e.g., poly(styrene-alt-maleic anhydride)) where “-alt-” indicates alternating polymeric blocks. It is understood that such blocks are exemplary and should not be considered to be limiting.

More specific di-block or tri-block copolymers include poly(styrene-b-vinyl pyridine) (PS-b-PVP), poly(styrene-b-butadiene) (PS-b-PBD), poly(styrene-b-isoprene) (PS-b-PI), poly(styrene-b-methyl methacrylate) (PS-b-PMMA), poly(styrene-b-alkenyl aromatics), poly(isoprene-b-ethylene oxide) (PI-b-PEO), poly(styrene-b-(ethylene-propylene)), poly(ethylene oxide-b-caprolactone), poly(butadiene-b-ethylene oxide) (PBD-b-PEO), poly(styrene-b-t-butyl(meth)acrylate), poly(methyl methacrylate-b-t-butyl methacrylate), poly(ethylene oxide-b-propylene oxide), poly(styrene-b-tetrahydrofuran), poly(styrene-b-dimethylsiloxane) (PS-b-PDMS), poly(styrene-b-ferrocenyldimethylsilane) (PS-b-PFS), poly(styrene-b-isoprene-b-ethylene oxide) (PS-b-PI-b-PEO), poly(styrene-b-isoprene-b-methyl methacrylate) (PS-b-PI-b-PMMA), poly(styrene-b-ferrocenyldimethylsilane-b-isoprene) (PS-b-PFS-b-PI), or a combination comprising at least one of the foregoing block copolymers.

Other block copolymer systems capable of forming phase separated structures with periodicities >80 nm can also be employed, including, for example, other block copolymer architectures capable of self assembly or self-organization.

The term “olefin block copolymer” or “OBC” means an ethylene/α-olefin multi-block copolymer and includes ethylene and one or more copolymerizable α-olefin comonomers in polymerized form, characterized by multiple blocks or segments of two or more polymerized monomer units differing in chemical or physical properties. The terms “interpolymer” and “copolymer” are used interchangeably herein. When referring to amounts of “ethylene” or “comonomer” in the copolymer, it is understood that this means polymerized units thereof. In some embodiments, the multi-block copolymer can be represented by the following formula:

(AB)ₙ

where n is at least 1, preferably an integer greater than 1, such as 2, 3, 4, 5, 10, 15, 20, 30, 40, 50, 60, 70, 80, 90, 100, or higher, “A” represents a hard block or segment and “B” represents a soft block or segment. Preferably, As and Bs are linked in a substantially linear fashion, as opposed to a substantially branched or substantially star-shaped fashion. In other embodiments, A blocks and B blocks are randomly distributed along the polymer chain. In other words, the block copolymers usually do not have a structure as follows.

AAA-AA-BBB-BB

In still other embodiments, the block copolymers do not usually have a third type of block, which comprises different comonomer(s). In yet other embodiments, each of block A and block B has monomers or comonomers substantially randomly distributed within the block. In other words, neither block A nor block B comprises two or more sub-segments (or sub-blocks) of distinct composition, such as a tip segment, which has a substantially different composition than the rest of the block.

Preferably, ethylene comprises the majority mole fraction of the whole block copolymer, i.e., ethylene comprises at least 50 mole percent of the whole polymer. More preferably ethylene comprises at least 60 mole percent, at least 70 mole percent, or at least 80 mole percent, with the substantial remainder of the whole polymer comprising at least one other comonomer that is preferably an α-olefin having 3 or more carbon atoms. In some embodiments, the olefin block copolymer may comprise 50 mol % to 90 mol % ethylene, preferably 60 mol % to 85 mol %, more preferably 65 mol % to 80 mol %. For many ethylene/octene block copolymers, the preferred composition comprises an ethylene content greater than 80 mole percent of the whole polymer and an octene content of from 10 to 15, preferably from 15 to 20 mole percent of the whole polymer.

The olefin block copolymer includes various amounts of “hard” and “soft” segments. “Hard” segments are blocks of polymerized units in which ethylene is present in an amount greater than 95 weight percent, or greater than 98 weight percent based on the weight of the polymer, up to 100 weight percent. In other words, the comonomer content (content of monomers other than ethylene) in the hard segments is less than 5 weight percent, or less than 2 weight percent based on the weight of the polymer. In some embodiments, the hard segments include all, or substantially all, units derived from ethylene. “Soft” segments are blocks of polymerized units in which the comonomer content (content of monomers other than ethylene) is greater than 5 weight percent, or greater than 8 weight percent, greater than 10 weight percent, or greater than 15 weight percent based on the weight of the polymer. In some embodiments, the comonomer content in the soft segments can be greater than 20 weight percent, greater than 25 weight percent, greater than 30 weight percent, greater than 35 weight percent, greater than 40 weight percent, greater than 45 weight percent, greater than 50 weight percent, or greater than 60 weight percent and can be up to 100 weight percent.

The soft segments can be present in an OBC at from 1 weight percent to 99 weight percent of the total weight of the OBC, or from 5 weight percent to 95 weight percent, from 10 weight percent to 90 weight percent, from 15 weight percent to 85 weight percent, from 20 weight percent to 80 weight percent, from 25 weight percent to 75 weight percent, from 30 weight percent to 70 weight percent, from 35 weight percent to 65 weight percent, from 40 weight percent to 60 weight percent, or from 45 weight percent to 55 weight percent of the total weight of the OBC. Conversely, the hard segments can be present in similar ranges. The soft segment weight percentage and the hard segment weight percentage can be calculated based on data obtained from DSC or NMR. Such methods and calculations are disclosed in, for example, U.S. Pat. No. 7,608,668, entitled “Ethylene/α-Olefin Block Inter-polymers,” filed on Mar. 15, 2006, in the name of Colin L. P. Shan, Lonnie Hazlitt, et al. and assigned to Dow Global Technologies Inc. In particular, hard and soft segment weight percentages and comonomer content may be determined as described in Column 57 to Column 63 of U.S. Pat. No. 7,608,668.

The olefin block copolymer is a polymer comprising two or more chemically distinct regions or segments (referred to as “blocks”) preferably joined in a linear manner, that is, a polymer comprising chemically differentiated units that are joined end-to-end with respect to polymerized ethylenic functionality, rather than in pendent or grafted fashion. In an embodiment, the blocks differ in the amount or type of incorporated comonomer, density, amount of crystallinity, crystallite size attributable to a polymer of such composition, type or degree of tacticity (isotactic or syndiotactic), regio-regularity or regio-irregularity, amount of branching (including long chain branching or hyper-branching), homogeneity or any other chemical or physical property. The present OBC is characterized by unique distributions of both polymer polydispersity (PDI or Mw/Mn or MWD), block length distribution, and/or block number distribution, due, in an embodiment, to the effect of the shuttling agent(s) in combination with multiple catalysts used in their preparation.

In an embodiment, the OBC is produced in a continuous process and possesses a polydispersity index, PDI, (or Mw/Mn) of from 1.4 to 3.5, 1.7 to 3.5, or from 1.8 to 3, or from 1.8 to 2.5, from 1.8 to 2.2 or from 1.4 to 2.8. When produced in a batch or semi-batch process, the OBC possesses a PDI from 1.0 to 3.5, or from 1.3 to 3, or from 1.4 to 2.5, or from 1.4 to 2.

In some embodiments, the olefin block copolymer possesses a molecular weight distribution fitting a Schultz-Flory distribution rather than a Poisson distribution. The OBC can have both a polydisperse block distribution as well as a polydisperse distribution of block sizes. This results in the formation of polymer products having improved and distinguishable physical properties. The theoretical benefits of a polydisperse block distribution have been previously modeled and discussed in Potemkin, Physical Review E (1998) 57 (6), pp. 6902-6912, and Dobrynin, J. Chem. Phys. (1997) 107 (21), pp 9234-9238.

The OBCs advantageously are ‘mesophase separated’ meaning that the polymeric blocks are locally segregated to form ordered mesodomains. Crystallization of the ethylene segments in these systems is primarily constrained to the resulting mesodomains. These mesodomains can take the form of spheres, cylinders, lamellae, or other morphologies known for block copolymers. Such OBCs and processes to make them are disclosed in, for example, U.S. Pat. No. 7,947,793. The average minimum dimension of a domain, such as perpendicular to the plane of lamellae, is generally greater than about 40 nm in the mesophase separated block copolymers. The average of the smallest distance between regularly-repeating block-block interfaces of the phase separated nanostructure is advantageously in the range of from about 20 nm to about 500 nm, preferably in the range of from about 50 nm to about 400 nm, and more preferably in the range of from about 60 nm to about 300 nm, or even more preferably in the range of about 60 nm to about 250 nm. In some embodiments, the mesophase separated polymers comprise olefin block copolymers wherein the amount of comonomer in the soft segments as compared to that in the hard segments is such that the block copolymer undergoes mesophase separation in the melt. The required amount of comonomer may be measured in mole percent and varies with each comonomer. A calculation may be made for any desired comonomer in order to determine the amount required to achieve mesophase separation. The minimum level of incompatibility, expressed as χN, to achieve mesophase separation in these polydisperse block copolymers is predicted to be χN=2.0 (I. I. Potemkin, S. V. Panyukov, Phys. Rev. E. 57, 6902 (1998)). Recognizing that fluctuations usually push the order-disorder transition in commercial block copolymers to slightly higher χN, a value χN=2.34 has been used as the minimum in the calculations below. Following the approach of D. J. Lohse, W. W. Graessley, Polymer Blends Volume 1: Formulation, ed. D. R. Paul, C. B. Bucknall, 2000, χN can be converted to the product of χ/v and M/ρ where v is a reference volume, M is the number average block molecular weight and ρ is the melt density. The melt density is taken to be 0.78 g/cm³ and a typical value of block molecular weight is approximately 25,500 g/mol based on a diblock at an overall molecular weight of 51,000 g/mol. χ/v for cases in which the comonomer is butene or propylene is determined using 130° C. as the temperature and then performing an interpolation or extrapolation of the data provided in Table 8.1 in the reference by Lohse and Graessley. For each comonomer type, a linear regression in mole percent comonomer was performed. For cases in which octene is the comonomer, the same procedure was performed with the data of Reichart, G. C. et al, Macromolecules (1998), 31, 7886. The entanglement molecular weight at 413 K (about 140° C.) in kg/mol is taken to be 1.1. Using these parameters, the minimum difference in comonomer content is determined to be, respectively, 20.0, 30.8 or 40.7 mole percent when the comonomer is octene, butene, or propylene. In some embodiments, the difference in comonomer content is greater than 18.5 mole percent.

In some embodiments, the mesophase separated olefin block copolymers are characterized by an average molecular weight of greater than 40,000 g/mol, a molecular weight distribution, Mw/Mn, in the range of from about 1.4 to about 2.8, and a difference in mole percent α-olefin content between the soft block and the hard block of greater than about 18.5 mole percent. In some embodiments, the OBCs have a Block Index of 0.1 to 1.0.

In an embodiment, the present olefin block copolymer possesses a most probable distribution of block lengths. In an embodiment, the olefin block copolymer is defined as having:

(A) Mw/Mn from 1.7 to 3.5, at least one melting point, Tₘ, in degrees Celsius, and a density, d, in grams/cubic centimeter, where in the numerical values of Tₘ and d correspond to the relationship:

Tm>−6553.3+13735(d)−7051.7(d)², and/or

(B) Mw/Mn from 1.7 to 3.5, and is characterized by a heat of fusion, AH in J/g, and a delta quantity, ΔT, in degrees Celsius defined as the temperature difference between the tallest DSC peak and the tallest Crystallization Analysis Fractionation (“CRYSTAF”) peak, wherein the numerical values of ΔT and ΔH have the following relationships:

ΔT>−0.1299(ΔH)+62.81 for ΔH greater than zero and up to 130 J/g

ΔT>48° C. for ΔH greater than 130 J/g

wherein the CRYSTAF peak is determined using at least 5 percent of the cumulative polymer, and if less than 5 percent of the polymer has an identifiable CRYSTAF peak, then the CRYSTAF temperature is 30° C.; and/or

(C) elastic recovery, Re, in percent at 300 percent strain and 1 cycle measured with a compression-molded film of the ethylene/α-olefin interpolymer, and has a density, d, in grams/cubic centimeter, wherein the numerical values of Re and d satisfy the following relationship when ethylene/α-olefin interpolymer is substantially free of crosslinked phase:

Re>1481−1629(d); and/or

(D) has a molecular fraction that elutes between 40° C. and 130° C. when fractionated using Temperature Rising Elution Fractionation (TREF), characterized in that the fraction has a molar comonomer content greater than, or equal to, the quantity (−0.2013) T+20.07, more preferably greater than or equal to the quantity (−0.2013) T+21.07, where T is the numerical value of the peak elution temperature of the TREF fraction, measured in ° C.; and/or,

(E) has a storage modulus at 25° C., G′ (25° C.), and a storage modulus at 100° C., G′(100° C.), wherein the ratio of G′ (25° C.) to G′ (100° C.) is in the range of 1:1 to 9:1.

The olefin block copolymer may also have:

(F) a molecular fraction which elutes between 40° C. and 130° C. when fractionated using TREF, characterized in that the fraction has a block index of at least 0.5 and up to 1 and a molecular weight distribution, Mw/Mn, greater than 1.3; and/or

(G) average block index greater than zero and up to 1.0 and a molecular weight distribution, Mw/Mn greater than 1.3. It is understood that the olefin block copolymer may have one, some, all, or any combination of properties (A)-(G). Block Index can be determined as described in detail in U.S. Pat. No. 7,608,668. Analytical methods for determining properties (A) through (G) are disclosed in, for example, U.S. Pat. No. 7,608,668, Col. 31, line 26 through Col. 35, line 44.

Suitable monomers for use in preparing an OBC include ethylene and one or more addition polymerizable monomers other than ethylene. Examples of suitable comonomers include straight-chain or branched α-olefins of 3 to 30, preferably 3 to 20, carbon atoms, such as propylene, 1-butene, 1-pentene, 3-methyl-1-butene, 1-hexene, 4-methyl-1-pentene, 3-methyl-1-pentene, 1-octene, 1-decene, 1-dodecene, 1-tetradecene, 1-hexadecene, 1-octadecene and 1-eicosene; cyclo-olefins of 3 to 30, preferably 3 to 20, carbon atoms, such as cyclopentene, cycloheptene, norbornene, 5-methyl-2-norbornene, tetracyclododecene, and 2-methyl-1,4,5,8-dimethano-1,2,3,4,4a,5,8,8a-octahydronaphthalene; di- and polyolefins, such as butadiene, isoprene, 4-methyl-1,3-pentadiene, 1,3-pentadiene, 1,4-pentadiene, 1,5-hexadiene, 1,4-hexadiene, 1,3-hexadiene, 1,3-octadiene, 1,4-octadiene, 1,5-octadiene, 1,6-octadiene, 1,7-octadiene, ethylidenenorbornene, vinyl norbornene, dicyclopentadiene, 7-methyl-1,6-octadiene, 4-ethylidene-8-methyl-1,7-nonadiene, and 5,9-dimethyl-1,4,8-decatriene; and 3-phenylpropene, 4-phenylpropene, 1,2-difluoroethylene, tetrafluoroethylene, and 3,3,3-trifluoro-1-propene.

In one embodiment, the olefin block copolymer has a melt index (MI) from 0.1 g/10 min to 30 g/10, or from 0.1 g/10 min to 20 g/10 min, or from 0.1 g/10 min to 15 g/10 min, as measured by ASTM D 1238 (190° C./2.16 kg). The composition may comprise more than one olefin block copolymer.

Preferably, the olefin block copolymer is produced via a chain shuttling process such as described in U.S. Pat. No. 7,858,706. In particular, suitable chain shuttling agents and related information are listed in Col. 16, line 39 through Col. 19, line 44. Suitable catalysts are described in Col. 19, line 45 through Col. 46, line 19 and suitable co-catalysts in Col. 46, line 20 through Col. 51 line 28. The process is described throughout the document, but particularly in Col. 51, line 29 through Col. 54, line 56. The process is also described, for example, in the following: U.S. Pat. No. 7,608,668; U.S. Pat. No. 7,893,166; and U.S. Pat. No. 7,947,793.

In one embodiment of the invention, the OBC is an ethylene/α-olefin block interpolymer that is mesophase separated and that comprises one or more hard segments and one or more soft segments having a difference in mole percent α-olefin content, wherein the ethylene/α-olefin block interpolymer is characterized by a molecular weight distribution (M_{w}/Mₙ) in the range of from about 1.4 to about 2.8, and a difference in mole percent α-olefin content between the soft segment and the hard segment of greater than about 18.5 mole percent.

It may be desirable to increase the selectivity of one phase of a phase separated block copolymer to the inorganic dielectric nanoparticle precursor, or to increase the concentration of the precursor in a particular phase. One method of accomplishing these goals is to modify one or more of the phases of a block copolymer prior to incorporation of the inorganic dielectric nanoparticle precursor. The phase separated block copolymers may be modified by, for example, grafting, hydrogenation, nitrene insertion reactions, or other functionalization reactions such as those known to those skilled in the art. Preferred functionalizations are grafting reactions using a free radical mechanism. Functionalizations that sepectively functionalize only one phase of a phase-separated block copolymer are especially preferred.

A variety of radically graftable species may be employed to functionalize the block copolymer. These species include unsaturated molecules, each containing at least one heteroatom. These species include, but are not limited to, maleic anhydride, dibutyl maleate, dicyclohexyl maleate, diisobutyl maleate, dioctadecyl maleate, N-phenylmaleimide, citraconic anhydride, tetrahydrophthalic anhydride, bromomaleic anhydride, chloromaleic anhydride, nadic anhydride, methylnadic anhydride, alkenylsuccinic anhydride, maleic acid, fumaric acid, diethyl fumarate, itaconic acid, citraconic acid, crotonic acid, and the respective esters, imides, salts, and Diels-Alder adducts of these compounds. These species also include silane compounds.

Radically graftable species of the silane class of materials may be attached to the polymer, either individually, or as relatively short grafts. Generally, materials of this class include, but are not limited to, hydrolyzable groups, such as alkoxy, acyloxy, or halide groups, attached to silicon. These species include, but are not limited to, vinylalkoxysilanes such as, for example, vinyltrimethoxysilane, vinyltriethoxysilane, vinyltriacetoxysilane, vinyltrichlorosilane, and the like. Vinyl triethoxysilane and vinyl trimethoxysilane are preferred examples of radically graftable species of the silane class of materials. Radically graftable silanes useful in this invention also include those having groups such as, for example, alkyl and siloxy groups, attached to silicon.

Other radically graftable species may be attached to the block copolymer. These species include, but are not limited to, methacrylic acid; acrylic acid; Diels-Alder adducts of acrylic acid; methacrylates including methyl, ethyl, butyl, isobutyl, ethylhexyl, lauryl, stearyl, hydroxyethyl, and dimethylaminoethyl; acrylates including methyl, ethyl, butyl, isobutyl, ethylhexyl, lauryl, stearyl, and hydroxyethyl; glycidyl methacrylate; trialkoxysilane methacrylates, such as 3-(methacryloxy)propyltrimethoxysilane and 3-(methacryloxy)propyl-triethoxysilane, methacryloxymethyltrimethoxysilane, methacryloxymethyltriethoxysilane; acrylonitrile; 2-isopropenyl-2-oxazoline; styrene; α-methylstyrene; vinyltoluene; dichlorostyrene; N-vinylpyrrolidinone, vinyl acetate, methacryloxypropyltrialkoxysilanes, methacryloxymethyltrialkoxysilanes and vinyl chloride.

Mixtures of radically graftable species that comprise at least one of the above species may be used, with styrene/maleic anhydride and styrene/acrylonitrile as illustrative examples.

A thermal grafting process is one method for reaction, however, other grafting processes may be used, such as photo initiation, including different forms of radiation, e-beam, or redox radical generation.

The functionalized block copolymers may also be modified by various chain extending or cross-linking processes, including, but not limited to peroxide-, silane-, sulfur-, radiation-, or azide-based cure systems. A full description of the various cross-linking technologies is described in U.S. Pat. Nos. 5,869,591 and 5,977,271. Cross-linking may be used, for example, to increase the toughness, hardness, or weatherability of the compositions disclosed herein.

Suitable curing agents may include peroxides, phenols, azides, aldehyde-amine reaction products, substituted ureas, substituted guanidines; substituted xanthates; substituted dithiocarbamates; sulfur-containing compounds, such as thiazoles, imidazoles, sulfenamides, thiuramidisulfides, paraquinonedioxime, dibenzoparaquinonedioxime, sulfur; and combinations thereof. Elemental sulfur may be used as a crosslinking agent for diene containing polymers.

In some systems, for example, in silane grafted systems, crosslinking may be promoted with a crosslinking catalyst, and any catalyst that will provide this function can be used in this invention. These catalysts generally include acids and bases, especially organic bases, carboxylic acids and sulfonic acids, and organometallic compounds including organic titanates, organic zirconates, and complexes or carboxylates of lead, cobalt, iron, nickel, zinc and tin. Dibutyltin dilaurate, dioctyltin maleate, dibutyltin diacetate, dibutyltin dioctoate, stannous acetate, stannous octoate, lead naphthenate, zinc caprylate, cobalt naphthenate, and the like, are examples of suitable crosslinking catalysts.

Rather than employing a chemical crosslinking agent, crosslinking may be effected by use of radiation or by the use of electron beam. Useful radiation types include ultraviolet (UV) or visible radiation, beta ray, gamma rays, X-rays, or neutron rays. Radiation is believed to effect crosslinking by generating polymer radicals that may combine and crosslink.

Dual cure systems, which use a combination of heat, moisture cure, and radiation steps, may be effectively employed. Dual cure systems are disclosed in U.S. Pat. Nos. 5,911,940 and 6,124,370. For example, it may be desirable to employ peroxide crosslinking agents in conjunction with silane crosslinking agents; peroxide crosslinking agents in conjunction with radiation; or sulfur-containing crosslinking agents in conjunction with silane crosslinking agents.

The functionalization may also occur at the terminal unsaturated group (e.g., vinyl group) or an internal unsaturation group, when such groups are present in the block copolymer. Such functionalization includes, but is not limited to, hydrogenation, halogenation (such as chlorination), ozonation, hydroxylation, sulfonation, carboxylation, epoxidation, and grafting reactions. Any functional groups, such as halogen, amine, amide, ester, carboxylic acid, ether, silane, siloxane, and so on, or functional unsaturated compounds, such as maleic anhydride, can be added across a terminal or internal unsaturation via known chemistry. Other functionalization methods include those disclosed in the following U.S. patents: U.S. Pat. No. 5,849,828, entitled, “Metalation and Functionalization of Polymers and Copolymers;” U.S. Pat. No. 5,814,708, entitled, “Process for Oxidative Functionalization of Polymers Containing Alkylstyrene;” and U.S. Pat. No. 5,717,039, entitled, “Functionalization of Polymers Based on Koch Chemistry and Derivatives Thereof.”

There are several types of compounds that can initiate grafting reactions by decomposing to form free radicals, including azo-containing compounds, carboxylic peroxyacids and peroxyesters, alkyl hydroperoxides, and dialkyl and diacyl peroxides, among others. Many of these compounds and their properties have been described (Reference: J. Branderup, E. Immergut, E. Grulke, eds. Polymer Handbook, 4th ed., Wiley, New York, 1999, Section II, pp. 1-76.). It is preferred for the species that is formed by the decomposition of the initiator to be an oxygen-based free radical. It is more preferable for the initiator to be selected from carboxylic peroxyesters, peroxyketals, dialkyl peroxides, and diacyl peroxides. Some of the more preferred initiators, commonly used to modify the structure of polymers, are listed in U.S. Pat. No. 7,897,689, in the table spanning Col. 48 line 13-Col. 49 line 29.

The block copolymer may be modified by azide modification. Compounds having one, two, or higher numbers of sulfonyl azide groups capable of C—H insertion under reaction conditions may be employed for functionalization of the block copolymers of this invention. Compounds having at least two sulfonyl azide groups capable of C—H insertion under reaction conditions are referred to herein as azide coupling agents. For the purpose of the invention, the poly(sulfonyl azide) is any compound having at least two sulfonyl azide groups reactive with a polyolefin under reaction conditions. Preferably the poly(sulfonyl azide)s have a structure X—R—X wherein each X is SO₂N₃ and R represents an unsubstituted or inertly substituted hydrocarbyl, hydrocarbyl ether or silicon-containing group, preferably having sufficient carbon, oxygen or silicon, preferably carbon, atoms to separate the sulfonyl azide groups sufficiently to permit a facile reaction between the polyolefin and the sulfonyl azide, more preferably at least 1, more preferably at least 2, most preferably at least 3 carbon, oxygen or silicon, preferably carbon, atoms between functional groups. While there is no critical limit to the length of R, each R advantageously has at least one carbon or silicon atom between X's and preferably has less than about 50, more preferably less than about 30, most preferably less than about 20 carbon, oxygen or silicon atoms. Within these limits, larger is better for reasons including thermal and shock stability. When R is straight-chain alkyl hydrocarbon, there are preferably less than 4 carbon atoms between the sulfonyl azide groups to reduce the propensity of the nitrene to bend back and react with itself. Silicon containing groups include silanes and siloxanes, preferably siloxanes. The term inertly substituted refers to substitution with atoms or groups that do not undesirably interfere with the desired reaction(s) or desired properties of the resulting functionalized polymers. Such groups include fluorine, aliphatic or aromatic ether, siloxane as well as sulfonyl azide groups when more than two polyolefin chains are to be joined. Suitable structures include R as aryl, alkyl, aryl alkaryl, arylalkyl silane, siloxane or heterocyclic, groups and other groups that are inert and separate the sulfonyl azide groups as described. More preferably R includes at least one aryl group between the sulfonyl groups, most preferably at least two aryl groups (such as when R is 4,4′ diphenylether or 4,4′-biphenyl). When R is one aryl group, it is preferred that the group have more than one ring, as in the case of naphthylene bis(sulfonyl azides). Poly(sulfonyl)azides include such compounds as 1,5-pentane bis(sulfonyl azide), 1,8-octane bis(sulfonyl azide), 1,10-decane bis(sulfonyl azide), 1,10-octadecane bis(sulfonyl azide), 1-octyl-2,4,6-benzene tris(sulfonyl azide), 4,4′-diphenyl ether bis(sulfonyl azide), 1,6-bis(4′-sulfonazidophenyl)hexane, 2,7-naphthalene bis(sulfonyl azide), and mixed sulfonyl azides of chlorinated aliphatic hydrocarbons containing an average of from 1 to 8 chlorine atoms and from about 2 to 5 sulfonyl azide groups per molecule, and mixtures thereof. Preferred poly(sulfonyl azide)s include oxy-bis(4-sulfonylazidobenzene), 2,7-naphthalene bis(sulfonyl azido), 4,4′-bis(sulfonyl azido)biphenyl, 4,4′-diphenyl ether bis(sulfonyl azide) and bis(4-sulfonyl azidophenyl)methane, and mixtures thereof.

Polyfunctional compounds capable of insertions into C—H bonds also include carbene-forming compounds such as salts of alkyl and aryl hydrazones and diazo compounds, and nitrene-forming compounds such as alkyl and aryl azides (R—N3), acyl azides (R—C(O)N3), azidoformates (R—O—C(O)—N3), sulfonyl azides (R—SO2-N3), phosphoryl azides ((RO)2-(PO)—N3), phosphinic azides (R2-P(O)—N3) and silyl azides (R3-S1-N3).

The functionalized polymers may also contain additives such as, but not limited to, antioxidants, slip agents, UV absorbers or stabilizers, antiblock agents, inorganic or organic fillers, color pigments or dyes and processing agents.

The inorganic dielectric nanoparticle precursor material is a material that can be selectively incorporated into one of the domains of the phase separated polymer and then converted into an inorganic dielectric nanoparticle material by subsequent processing. The term “inorganic dielectric nanoparticle material” refers to a material having a refractive index that is different than the refractive index of the block copolymer phase in which it is embedded. Advantageously, the inorganic dielectric nanoparticle material has a refractive index of at least 1.45, at least 1.70, at least 1.90 or at least 2.0.

In some embodiments, the precursor selectively locates within one of the domains by preferential swelling driven by chemical or physical differences in the two phases, e.g., solubility or crystallinity, such that the solvent containing the precursor material swells one domain relative the other. In other embodiments, the phase separated polymer contains functionality that favors selective incorporation of the precursor material, such as reactive functionality. A combination of these two methods can also be used to selectively locate the precursor material in one phase.

After incorporation of the inorganic dielectric nanoparticle precursor material into a selected polymer phase, that polymer phase is further treated to obtain the final composition of the invention. For example, titanium isopropoxide can be selectively infiltrated into the soft domain of a mesophase separated OBC and then reacted via an in situ polycondensation in the organic polymer matrix via a sol-gel type process to produce an OBC containing a high refractive index titanium oxide material predominantly in one polymer phase.

Examples of the inorganic dielectric precursor material include metal alkyls or alkoxides, such as isopropoxides, of titanium, zirconium, hafnium, aluminum, silicon, and the like, which react to form metal oxides. In addition, nitrides, phosphides, arsenides, sulfides, selenides, and tellurides may also be used. Precursors include, for example, compounds that can be converted into the Group 4 oxides TiO₂, ZrO₂, and HfO₂; zinc oxide; Group 15 derivatives of gallium, especially gallium nitride, gallium arsenide, and gallium phosphide; Group 15 derivatives of aluminum, especially aluminum nitride, aluminum oxide, and combinations of the like; Group 16 derivatives of silicon, especially silicon oxide, silicon nitride, and combinations of the like. Group 16 derivatives of tin, especially tin oxide, and combinations of the like. Group 4 compounds are preferred. Examples of suitable Group 4 compounds include Group 4 metal hydrocarbyloxides, especially those of the following general formula:

M(OR)₄

wherein M is Ti, Zr, or Hf; and R is in each occurrence independently C₁-C₁₂ hydrocarbyl, preferably C₁-C₃ alkyl. Specific examples include titanium tetramethoxide, titanium tetraethoxide, titanium tetraisopropoxide, titanium tetrabutoxide, titanium tetraphenoxide, zirconium tetramethoxide, zirconium tetraethoxide, zirconium tetraisopropoxide, zirconium tetrabutoxide, zirconium tetraphenoxide, hafnium tetramethoxide, hafnium tetraethoxide, hafnium tetraisopropoxide, hafnium tetrabutoxide, and hafnium tetraphenoxide. Titanium tetraisopropoxide is especially preferred. Other suitable compounds include diethyl zinc, titanium tetrabenzyl, zirconium tetrabenzyl, hafnium tetrabenzyl, and trimethyl gallium. The skilled artisan will appreciate that there are numerous precursor compounds that may be used to prepare inorganic dielectric nanoparticles. The precursor material can also be a single-source mixed metal sol-gel precursor as described by Warren et al. in WO2008/031108. Mixtures of precursor materials may be employed.

The inorganic dielectric precursor material is employed in an amount sufficient to provide the final composition with the desired refractive properties. For example, the amount of precursor may be selected to impart a specific composite refractive index to the modified polymer phase to produce the desired optical contrast reflectivity in the phase separated polymeric material. Advantageously, the amount of precursor employed is from 0.5 to about 70 wt %, more preferably from 5% to about 50%, based on the combined weight of the precursor and the infiltrated polymer phase. For the purposes of the invention, the term “infiltrated polymer phase” means the phase of the copolymer in which the precursor, and subsequently the dielectric particle, is predominantly located.

The invention includes a process for producing a composite structure, the process comprising:
1. providing a phase-separated block copolymer;
2. selectively incorporating an inorganic dielectric nanoparticle precursor into one of the phases;
3. converting the precursor into an inorganic dielectric nanoparticle material; and
4. optionally modifying the dimensions of the composite structure after the conversion process.

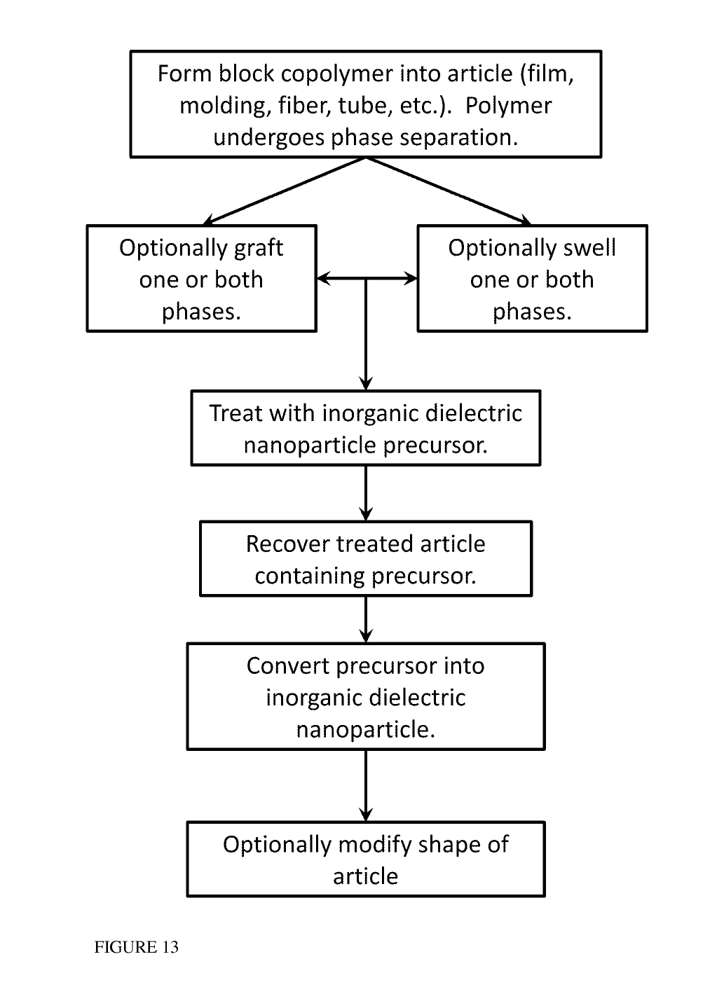

One embodiment of the process is shown in FIG. 13.

One embodiment of the invention can be described as follows. One of the copolymer phases is grafted and will become the infiltrated polymer phase. An inorganic dielectric precursor is mixed with a solvent for the purpose of introducing the precursor into the infiltrated polymer phase. The precursor selectively reacts with the grafts of the copolymer. The resulting precursor-reacted copolymer is hydrolyzed to form the inorganic species in the copolymer. Solvent, water, and other volatiles, if present, are then removed. The product nanocomposite may be useful for the manipulation of light.

In one embodiment, the precursor compound is selectively incorporated into one phase of a phase-separated block copolymer by taking advantage of chemical interactions between the precursor compound and the molecular structure of one phase of the block copolymer. These chemical interactions can involve covalent or ionic bonding, coordinate-covalent bonding, solubility, or polar-polar interactions. For example, a phase-separated block copolymer of polystyrene-b-polymethyl methacrylate can be contacted with a solution containing titanium tetraisopropoxide. The titanium tetraisopropoxide will selectively interact with the polar carboxylate groups of the polymethyl methacrylate block via polar-polar, or coordinate covalent, bonding preferentially over reaction with the non-polar polystyrene block. As a result, substantially all of the titanium tetraisopropoxide precursor will migrate and be preferentially located within the polymethylmethacrylate block as opposed to the polystyrene block.

Solubility can be used to selectively disperse the precursor into one phase of a phase-separated block copolymer. For example, precursors containing long-chain aliphatic groups can be used to selectively partition the precursor between a polar and a non-polar phase.

The selectivity of a precursor compound for one block over another in a phase-separated block copolymer after the incorporation process can be expressed by the equation:

$${S}_{p} = \frac{{[ A ]}_{p}}{{[ B ]}_{p}}$$

wherein [A]ₚ is the average molar concentration of the precursor compound in phase A of an A-b-B block copolymer; and [B]ₚ is the average molar concentration of the precursor compound in phase B. In various embodiments of the invention, Sₚ is at least 3, at least 20, at least at least 50, at least 100, or at least 1000.

In a similar manner, the selectivity of the inorganic dielectric nanoparticle for one block phase over another in a phase-separated block copolymer after the precursor conversion process can be expressed by the equation:

$${S}_{N} = \frac{{[ A ]}_{N}}{{[ B ]}_{N}}$$

wherein [A]_{N} is the average concentration of the precursor compound in phase A of an A-b-B block copolymer; and [B]_{N} is the average concentration of the precursor compound in phase B. In various embodiments of the invention, S_{N} is at least 3, at least 20, at least at least 50, at least 100, or at least 1000.

When both phases of a phase separated block copolymer are chemically similar, alternative methods may be used to achieve the desired selective incorporation of the precursor compound into one of the block phases. Phase separated OBCs can phase separate into a crystalline domain and an amorphous domain. It is possible to selectively swell the amorphous domain with a solvent, which can contain, for example, a grafting agent and an initiator, such as a peroxide.

The precursor compound can be dispersed into the block copolymer as a solution or as a neat compound. In most cases, it is desirable to first dissolve the precursor compound in a suitable solvent, followed by soaking the polymer structure in the resulting solution. Suitable solvents will depend on the specifics of the block copolymer and the precursor compound, but the solvent should be inert with respect to reaction with either the precursor compound or the block copolymer, and preferably will be selectively absorbed into one phase of the phase-separated block copolymer. In addition, it is desirable that the solvent have sufficient volatility so as to be easily removed from the polymer structure following dispersion of the precursor compound.

The precursor compound can be converted in the copolymer into an inorganic dielectric nanoparticle using a variety of techniques, depending on the nature of the precursor compound. For example, water can be used to convert Group 4 metal alkoxides into the corresponding Group 4 metal oxide nanoparticles by hydrolysis of the phase-separated structure containing the precursor compound. For example, titanium tetraisopropoxide dispersed selectively in one phase can be converted into titania (TiO₂) by exposure of the structure to water. The structure can be exposed to ambient atmospheric water, dipped into liquid water, or exposed to steam.

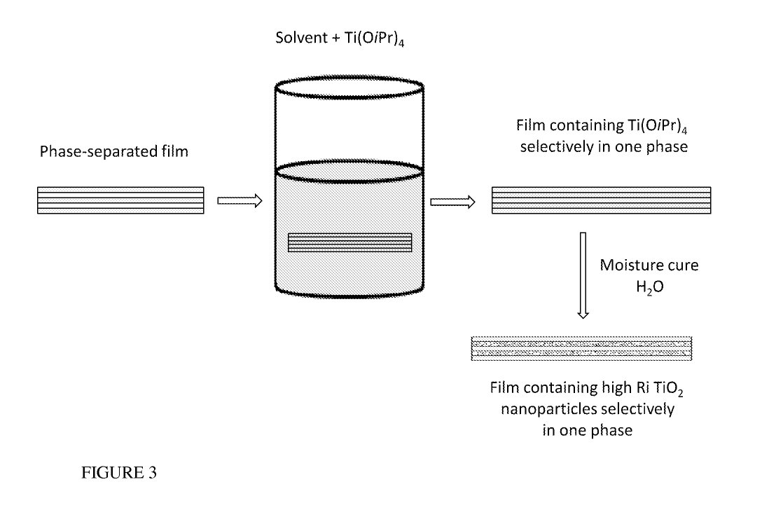

In one embodiment of the invention, nanocomposites are formed by a process comprising selectively placing the inorganic dielectric precursor into one phase of the phase separated block copolymer, followed by swelling the grafted block copolymer in the presence of the precursor, followed by converting the precursor in the copolymer to the inorganic species in the copolymer. For example, according to one embodiment, nanocomposites are formed from pre-formed films or sheets of silane-grafted phase separated block copolymers by swelling the films or sheets in a mixture of solvent and titanium isopropoxide, followed by hydrolysis to form TiO₂, and removal of solvent from the swollen sheets. This solvent-based process is amenable to any material that can be swollen with solvent including, for example, ethylene and propylene-based elastomers. For semi-crystalline materials that cannot be effectively swollen, the inorganic dielectric precursor can be added in a melt blending process such as an extruder to create a dispersion of the material. Representative examples of nanocomposites of TiO₂ and phase-separated block copolymers formed using this solvent swelling process are described below. A schematic of one embodiment of the process is shown in FIG. 3.

Procedures for grafting polymers are well known to those skilled in the art. In one embodiment of the invention, the grafting is accomplished using grafting techniques and agents described herein. The amount of grafting agent employed is an amount suitable to achieve the desired amount of grafting.

Techniques for swelling polymers are well known to those skilled in the art. Suitable solvents can be selected based on the copolymer phase to be swollen. In the case of OBCs, suitable solvents include, for example, hydrocarbons such as toluene, hexane, octane, kerosene, mixed branched aliphatic hydrocarbons such as ISOPAR (available from Exxon Chemical), mineral oil, and the like. The amount of solvent employed is an amount suitable to achieve the desired amount of swelling. The amount of solvent is not particularly critical and advantageously can be from 1 weight part of solvent per 100 weight parts of block copolymer to a large excess, such as would be obtained by immersing the block copolymer article into a large volume of solvent containing the inorganic dielectric precursor. Mixtures of solvents can be employed.

The inorganic dielectric precursor can be introduced with the solvent into the targeted phase of the phase separated block copolymer. In one embodiment of the invention, the polymer is swollen first, then the precursor is introduced to the swollen polymer. Preferably, the precursor is introduced essentially simultaneously with the solvent.

In one embodiment of the invention, the distribution of inorganic nanoparticles can be altered by allowing the films to swell for longer times, or can be altered by using melt mixing to introduce the inorganic precursor.

After the precursor is introduced into the polymer, it is converted in situ to the inorganic dielectric material, which advantageously is in the form of nanoparticles. Techniques for converting the inorganic precursor are also well known to those skilled in the art. For example, when the precursor is titanium isopropoxide, it can be converted to titania by hydrolysis.

The inorganic dielectric nanoparticle material is a dielectric material that is contained within the composition of the invention and serves to interact with light, which can be in the ultraviolet, visible, near IR or other wavelengths. Examples of the inorganic dielectric material include titanium oxide, silicon oxide, aluminum oxide, zirconium oxide, tin oxide, gallium oxide and hafnium oxide.

The composition may be designed to alter the light transmission or reflectance properties of articles made from the composition. In various embodiments of the invention, the relative difference in refractive index between phases of the composition is at least 0.002, at least 0.025, at least 0.05, at least 0.10, or at least 0.20, measured at the yellow doublet sodium D-line, with a wavelength of 589 nanometers. The magnitude of the relative difference in refractive index between phases of the nanocomposite will be determined by a combination of optical effect desired, article thickness within the direction of interacting light and the number of discrete phases contained therein. The inorganic, dielectric material in the composite advantageously has a refractive index of at least 1.4, at least 1.5, at least 1.7, or at least 2.5.

In one embodiment of the invention, the composition has a particle concentration gradient that is achieved relative to the physical dimension of the film or finished article by optimization of solvent swell parameters. The particle-containing phase does not need to be evenly distributed throughout an article. The creation of inorganic dielectric nanoparticles preferentially within one phase of a phase separated polymer material can be further enhanced by utilizing the defined swelling front of the swelling solution.

An article can be produced that contains inorganic dielectric nanoparticles only within the predetermined phase located within the vicinity of the outer surface of an article when the solvent diffusion is regulated to only the partial thickness of the article. This enables a surface skin of material that represents this invention without necessitating the homogeneous distribution of particles throughout the selected phase of the phase separated polymer material and article. For example, a gradient of inorganic particles relative to position within the structure but not specifically within an individual mesophase would be advantageous to guide or redirect incoming light. For example, the swelling front created by the swelling solvent intermixed with the reactive species can be controlled to create a transition region of particle-containing mesophase and the same mesophase not containing the dielectric particle. A cylinder of this composition where the solvent swelling only occurs radially in towards the center in a partial format can be created using this principle. The cylinder can be stretched along the long axis of the original cylinder. The initial structure of partial inorganic dielectric nanoparticles concentration which changes from the outside (high) to the inside (low or zero) is preserved but is reduced in diameter and increased in length.

The nanocomposite compositions of the invention can be used for the manufacture of a wide range of articles having the ability to manipulate light. In one embodiment of the invention, the composition is able to manipulate at least one portion of the wavelength spectrum in the 0.3 to 2.5 micron wavelength region. The composition can be formed into useful shapes, such as films and sheets. The shapes, after development of the intended inorganic dielectric nanoparticle distribution, may be altered by further physical, thermal and/or chemical treatment. For example, a film prepared using the composition where the full uniform distribution of the inorganic dielectric nanoparticles is not achieved relative to the shape, can be further modified by reducing one or more dimensions by thermomechanical processing in local areas in some periodic pattern to enable constructive interference of incoming light. In one embodiment of the invention, the composition is at least partially in film or sheet form, which optionally has been stretched or subjected to thermomechnical processing in at least one dimension.

The compositions of the invention can be employed in the manufacture of photonic structures, such as reflective films, antireflective films, selective band pass films or filters, wave guides, patterns, light directing or light separating structures, simple or complex lens structures and polarizing structures. The films and optical bodies of the invention can be used in many horticultural applications where it is desired to filter out or transmit specific wavelengths of light that are optimal for controlled plant growth. These photonic structures can be a direct result of the film forming and post reaction or incorporation of the inorganic dielectric material based particle predominately found within one of the copolymer phases or as a result of some thermal mechanical post processing step where the initial multiphasic structure is modified as a result of altering the geometry of the initial structure. Structures resulting from the local deformation of the mesophasic film, before or after inorganic dielectric particle incorporation predominately in one of the phases, are included. Examples of post processing can include, but are not limited to, simple stretching or tentering of the film whereby the length and/or width is increased and a relative (by volume) decrease in the initial film thickness results in a proportional decrease in the multiphasic structure thickness thereby achieving or tuning the light interaction ability of the film. This enables the achievement of mesophase or microphase minimum dimensions not inherently possible based on the thermodynamically favorable phase separation length scale determined by the difference in solubility parameters and molecular weight.

In one embodiment of the invention, the article is a film or sheet that is at least 80%, at least 90%, or at least 95%, reflective to light of a chosen wavelength. In one embodiment of the invention, the article is a film or sheet that is at least 80%, at least 90%, or at least 95%, absorptive of light of a chosen wavelength.

In another aspect of the invention, this modification of the minimum phasic dimension can be achieved in a selective area relative to the entire article and used to create simple lenses or reflectors. Creating a periodic array of these different optically interfering structures is useful in producing arrays, gratings and holograms.

Photonic structures have been employed in photovoltaic modules or packages with an emphasis in their incorporation or utilization increasing as the overall efficiency of the active semiconductor material has improved making the application more economically viable. Typical photonic structures employed in current photovoltaic panels are anti-reflective (AR) in performance and often described as anti-reflective coatings (ARCs) based on their geometry of incorporation, that of a thin coating or series of coatings applied at the interior surface of the top or front glass component. The purpose of these ARCs is to minimize the total amount of reflected light (sunlight) that is incident on the photovoltaic panel in an effort to deliver the greatest amount of broad spectrum light to the active semiconductor layer thereby enabling the greatest power generation per amount of incoming sunlight. This is often referred to as conversion efficiency. Typical ARCs are created by depositing a series of very thin (often less then 100 um for each individual layer), where the series may contain as few as 3 layers or sometimes greater then 7, with each distinct layer having a slightly different refractive index. There are many commercially available computer simulation programs that can be used to design this ARC using the material property of refractive index and desired total number of individual film layers. Surface finish quality is very important as is the absolute control of layer thickness and refractive index. These films generally are mechanically very poor based on their film thickness and may require a substrate for deposition that can withstand the required thin film deposition temperature.

Phase separated block copolymer nanocomposite films of the invention offer the potential to decouple the requirements of a deposition substrate, associated deposition process temperature and the ability to selectively enhance or reduce the passage of only part of the sunlight wavelength spectrum. The number of discrete layers, their respective thicknesses and optical properties can all be manipulated to achieve one or multiple objectives of minimization or enhancement of passage of light. For example, in the case of a solar cell or panel, the composition or film can be manipulated to enable the active semiconductor layer to most efficiently convert light to electrons, or to potentially capture light and enable multiple opportunities for the active semiconductor layer to convert light to electrons.

The article may comprise multiple repeated phases. For example, the number of mesophases in a film can be at least 10 layers, at least 100 layers, or at least 1000 layers. The layers may be stretched, unstretched, or a combination thereof.

The composition may be used in the manufacture of articles such as, for example, apparel, such as shoes, packaging or optoelectronic devices such as building integrated photovoltaic devices, solar cells and light emitting devices, such as LEDs.

The articles may find use in nearly all areas from everyday life to the most advanced science, e.g., light detection, telecommunications, information processing, lighting, metrology, spectroscopy, holography, medicine (surgery, vision correction, endoscopy, health monitoring), military technology, laser material processing, visual art, biophotonics, agriculture, and robotics. Unique applications of photonics continue to emerge. Economically important applications for photonic devices include optical data recording, fiber optic telecommunications, laser printing (based on xerography), displays, and optical pumping of high-power lasers.

Photonic structures, especially thin-film photonic structures, can be usefully employed in a variety of consumer devices, including barcode scanners, printers, CD/DVD/Blu-ray devices, and remote control devices. In the field of telecommunications, such structures are useful for a variety of applications, including optical fiber communications and optical down conversion. The skilled artisan will appreciate that there are numerous other applications for photonic devices.

The composition of the invention can be used to prepare optical filters. In one embodiment of the invention, the filter exhibits the at least one of the following properties: at least 90% transmittance of light of the desired wavelength; low angle and/or variable angle light acceptance as a result of, e.g., multiple controlled surface textures and/or topographies that result in excellent light capture; a tunable refractive index, e.g., the filter can be manufactured with a desired refractive index as a result of using multiple layers, layer thicknesses, layer compositions, nanoparticle concentrations, and nanoparticle compositions; compatibility with industrially accepted photovoltaic module manufacturing processes, e.g., lamination; heat management via the reflection of undesired wavelengths; UV management; and protected optical surfaces, e.g., via self-cleaning surfaces.

In addition, the composites of the invention are useful in a wide range of applications. This invention offers the independent modification of several morphological and optical aspects of the nanocomposite to achieve a wide range of desirable properties. Examples of selectable modifications include particle morphology (aspect ratios from 1 to greater then 100, as well as three dimensional architectures), distribution of the particle containing mesophase, optical interactions of the particle, as well as the multiplicity effect of numerous optically discrete interfaces. Additional examples of applications include: capacitors for energy storage; battery membranes for charge separation; light extraction and light guiding for LEDs; upconverters and downconverters. The composite of the invention can be designed to produce articles, e.g., films and sheets, of desired colors.

### SPECIFIC EMBODIMENTS OF THE INVENTION

The following examples are given to illustrate the invention and should not be construed as limiting its scope. All parts and percentages are by weight unless otherwise indicated.

### Example 1

### OBC Grafted with Vinyltrimethoxy Silane

A high octene phase separated OBC is obtained according to the method used to prepare the polymer of Example 1b of U.S. Pat. No. 8,124,709. The high octene OBC has a density of 0.8774 g cm⁻³, a number-average molecular weight, Mn, of 42.7 kg mol⁻¹, a polydispersity index of 1.9, and a difference in refractive index between the hard and soft phases of approximately 0.04.

(45.0 g), vinyl trimethoxy silane (1.15 g), and Luperox™ 101 peroxide initiator (0.0395 g) and the OBC are added to a vial and shaken overnight to allow the OBC to absorb the vinyl trimethoxysilane and Luperox 101. The resulting material is added to the small bowl of a Haake mixer at 190° C. and is reacted for 15 min at 45 rpm. The polymer then is removed from the Haake and pressed at 110° C. into a large film, which is placed in a vacuum oven at 50° C. for 2 hr to remove excess unreacted monomer.

The polymer is analyzed for silane content by preparing thin films via compression molding and analyzing them via Fourier Transform Infrared (FTIR) spectroscopy. Based upon a calibration curve, the silane content is found to be 2.3%, and is predominantly in the high octene phase of the OBC.

### Example 2

### Nanocomposite Preparation

Compression molded sheets are prepared by first heating the silane-grafted OBC of Example 1 to 190° C. for 15 min, then compression molding the silane-grafted OBC under 20,000 lbs pressure for 10 min at 170° C., and then cooling the 50 mil thick sheets between cooling platens at 15° C. at 20,000 lbs for 10 min. After removing the molded samples, they are placed in a foil bag under nitrogen to prevent reaction of the silane group with water vapor in the air.

To incorporate TiO₂, a compression molded sheet is soaked for 45 min in a 70:30 toluene:titanium isopropoxide mixture. The soaked sheet is removed, and is moisture cured by placing it into a scintillation vial in a ZIPLOC bag containing a wet paper towel. The ZIPLOC bag is closed and placed in the oven at 70° C. for 2 hr.

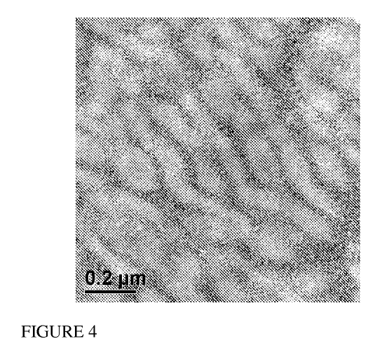

A transmission electron microscopy (TEM) image of the nanocomposite material is shown in FIG. 4. The image clearly shows dark boundaries composed of small electron dense particles, which are surrounded by lighter hard block domains. The fine granular particles are believed to be TiO₂ and are preferentially located in the soft domains.

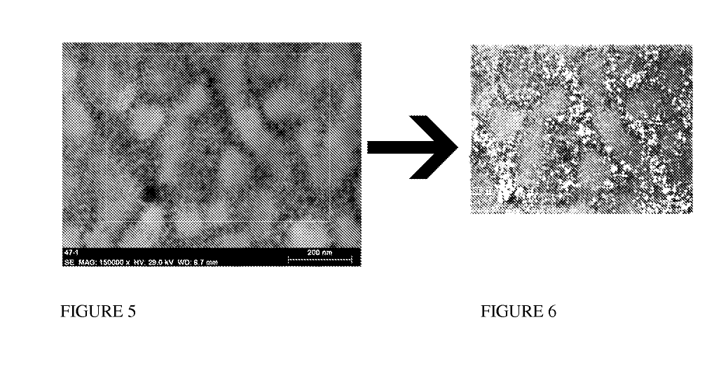

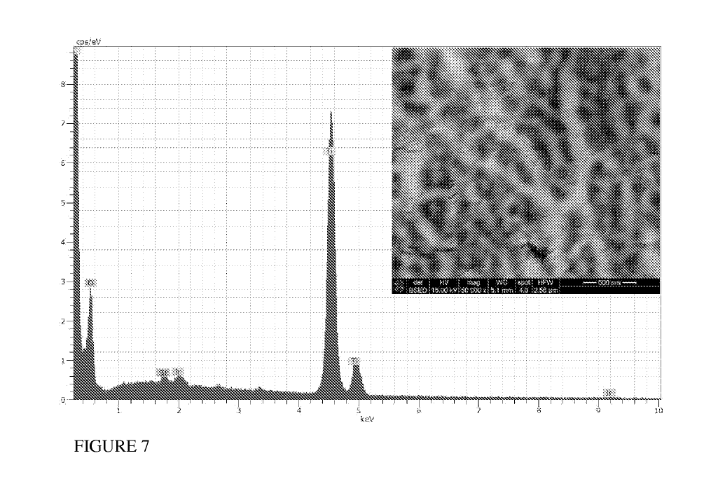

The fine granular particles are confirmed to be TiO₂ by the following procedure. Scanning transmission electron microscopy (STEM) is used to analyze the material since elemental capabilities are not available on the TEM. FIG. 5 shows the STEM image of the nanocomposite. The boxed region is used for mapping, and a black and white version of a false color elemental map collected from the STEM image verifies that the concentration of titanium is greater in the soft blocks (the higher contrast boundaries between the lighter contrast hard block domains). The STEM image is overlaid on the elemental map for better clarity, and the combined image is shown in FIG. 6. This data clearly shows that TiO₂ is found preferentially within the soft domains. This type of selective location is very difficult to achieve.

Backscatter scanning electron microscopy (SEM) is also used to confirm the presence of TiO₂ in the soft domains. Elemental analyses of the high contrast boundaries shown in FIG. 5, which correspond to the soft domains in backscatter SEM, verify that the titanium and oxygen are present in much greater concentration in the soft block region.

Comparative Experiment A (not an Embodiment of the Invention)

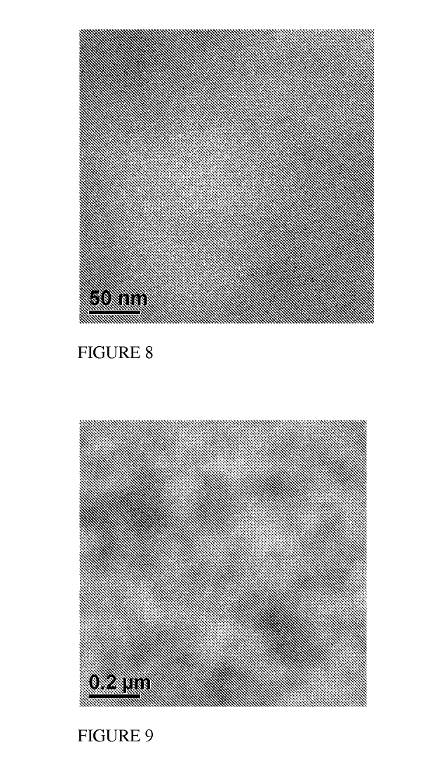

TEM images of a film of the untreated phase separated OBC employed in Example 1 are shown in FIGS. 8 and 9. The images are consistent with a homogeneous material with no visible nanoparticle features.

### Example 3

The general procedure in Example 2 is followed to make a series of polymer films according to this invention. The spacing between the phase-separated layers is adjusted by blending between 1-30% by weight of high density polyethylene with the phase separated olefin block copolymer, which has the effect of swelling the hard-block phase of the phase-separated film structure. In this manner, a series of polymer films are prepared that reflect light at a series of wavelengths. A series of 4 films are prepared according to this method with peak reflections as follows:

| Film Sample | Peak reflection, nm |
|---|---|
| A | 885 |
| B | 689 |
| C | 590 |
| D | 476 |

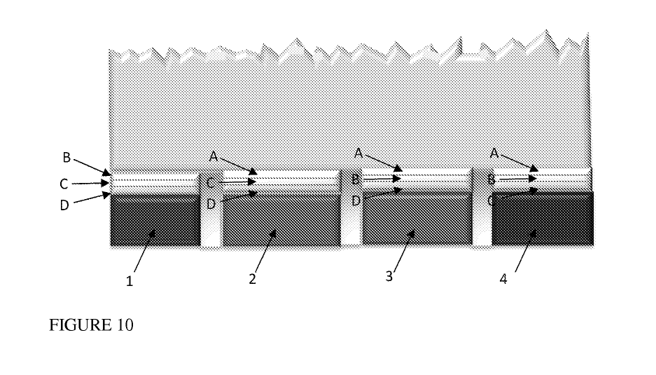

These films are used to construct a photovoltaic device by acting as band-pass filters, selective for specific sections of spectrum of sunlight. The films are laminated to a textured plate of glass as shown in FIG. 10. Each stack of light management film reflects specific frequencies of light, while allowing others to pass. The light that passes through the light management film stack is directed to a solar cell with a band-gap matched to the frequencies of light that is passed through the band-pass filters. In this manner, a high efficiency photovoltaic device is constructed. The glass plate is textured to trap incident light through multiple internal reflections. Appropriate solar cells for this device can be selected as follows:

| Solar Cell | Composition | Band Gap |
|---|---|---|
| 1 | GaAs | 1.4 eV |
| 2 | Ga_{0.52}In_{0.48}P | 1.8 eV |
| 3 | Al_{0.20}Ga_{0.32}In_{0.48}P | 2.1 eV |
| 4 | Ga_{0.85}In_{0.15}N | 2.6 eV |

A device of Example 3 is shown in FIG. 10.

### Example 4

The procedure of Example 3 is repeated to prepare a series of 2 films with peak reflections as follows:

| Film Sample | Peak reflection, nm |
|---|---|
| A | 885 |
| C | 590 |

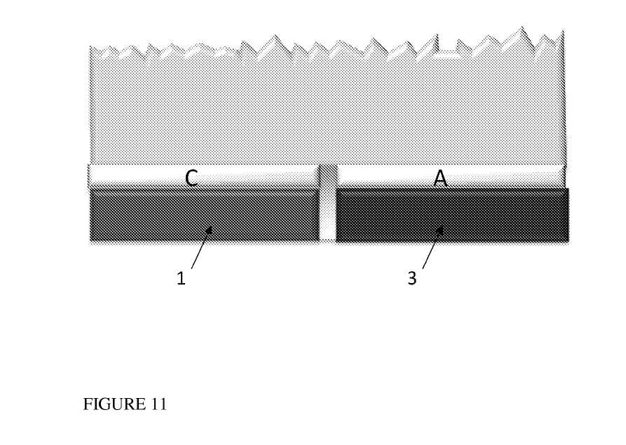

The films are laminated to a textured plate of glass in FIG. 11. Appropriate solar cells for this device can be selected as follows:

| Solar Cell | Composition | Band Gap |
|---|---|---|
| 1 | GaAs | 1.4 eV |
| 3 | Al_{0.20}Ga_{0.32}In_{0.48}P | 2.1 eV |

A device of Example 4 is shown in FIG. 13000.

### Example 5

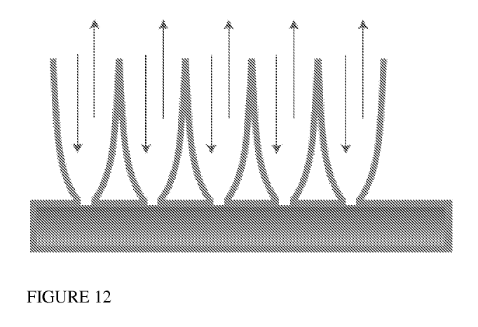

This example is similar to Example 4 except that the textured glass plate is replaced by a device as shown in FIG. 12.

The films can be used to construct a photovoltaic device by acting as band-pass filters, selective for specific sections of spectrum of sunlight. The films are laminated to a textured plate of glass containing a plurality of parabolic mirrors, as shown in FIG. 12. It is also possible to omit the glass plate from this structure.

It is evident to those skilled in the art that there is a clear need for utilizing light splitting optics with optoelectronic devices, and more specifically with photovoltaic devices, to improve the overall efficiency of the photovoltaic device. For example A. Goetzberger et al., Light Trapping, A New Approach To Spectrum Splitting, Solar Energy Materials & Solar Cells, Vol. 92 (2008) pp. 1570-1578. presents a type of light trap that enables photovoltaic conversion with separate solar cells optimized for different frequency (wavelength) bands of light. Goetzberger describes a means of concentrating incident light onto a reflective surface with openings, and trapping the light within a light trap such that the light bounces around within the light trap until it encounters a solar cell with the appropriate wavelength spectrally matched band gap required to absorb that wavelength. Surprisingly, the composite of the invention can be designed to have a unique index of refraction that can be tailored to split light. Such a composite is desirable and would improve the efficiency of photovoltaic devices.

1. A composition comprising a phase separated block copolymer and an inorganic dielectric nanoparticle, wherein the nanoparticle is dispersed in the copolymer and is present primarily in one phase and the composition has an S_{N} of at least 3.

2. The composition of claim 1 wherein the composition is able to manipulate one portion of the wavelength spectrum in the 0.3 to 2.5 micron wavelength region.

3. The composition of claim 1 wherein the copolymer is an OBC.

4. The composition of claim 1 wherein the copolymer is a mesophase separated block copolymer.

5. The composition of claim 1 wherein one copolymer is grafted with vinyl triethoxysilane or vinyl trimethoxysilane.

6. The composition of claim 1 wherein the composition is at least partially in film or sheet form, which optionally has been stretched or subjected to thermomechnical processing in at least one dimension.

7. An article comprising the composition of claim 1.

8. The article of claim 7 wherein the article comprises a light splitting film.

9. The article of claim 7 wherein the article comprises a polarizing film, an antireflective film, a reflective film, a band pass filter, a brightness enhancement film, a light re-directing film, or a solar heat control film.

10. A photovoltaic device comprising the article of claim 7.

11. A photovoltaic device according to claim 10 wherein the device comprises a plurality of semiconductors, wherein at least 2 of the semiconductors have different bandgaps.

12. A photovoltaic device according to claim 11 wherein light that enters the article passes through a film, wherein the film separates the light to a desired bandwidth, and wherein the desired bandwidth of light is passed to a solar cell matched to the frequency of the desired bandwidth of light.

13. A process comprising:
(a) providing a phase-separated block copolymer;
(b) selectively incorporating a inorganic dielectric precursor into one of the phases of the copolymer;
(c) converting the precursor into a inorganic dielectric material; and
(d) recovering a composition of claim 1.

14. The process of claim 13 further comprising forming an article from the composition.
